(19) United States
(12) Patent Application Publication
(10) Pub. No.: US 2024/0339966 A1
(43) Pub. Date: Oct. 10, 2024

(54) SEMICONDUCTOR DEVICE

(71) Applicant: Sumitomo Electric Industries, Ltd., Osaka (JP)

(72) Inventor: Ken KIKUCHI, Osaka-shi (JP)

(73) Assignee: Sumitomo Electric Industries, Ltd., Osaka (JP)

(21) Appl. No.: 18/605,045

(22) Filed: Mar. 14, 2024

(30) Foreign Application Priority Data
Apr. 6, 2023 (JP) 2023-062333

(51) Int. Cl. H03F 1/22; H01L 27/06; H01L 27/088; H01L 29/423; H03F 3/193

(52) U.S. Cl. CPC H03F 1/223; H01L 27/0629; H01L 27/088; H01L 29/42316; H03F 3/193

(57) ABSTRACT

A semiconductor device includes a substrate, a first FET (Field Effect Transistor) configured to include a first source electrode electrically connected to a first reference potential, a first gate electrode electrically connected to an input terminal, and a first drain electrode, a second FET configured to include a second source electrode, a second gate electrode, and a second drain electrode electrically connected to an output terminal, the second FET being arranged in a first direction with respect to the first FET, a first wiring configured to electrically connect the first drain electrode to the second source electrode, and s capacitor configured to be provided between the first FET and the second FET, and have a first end electrically connected to the second gate electrode and a second end electrically connected to a second reference potential.

### CROSS REFERENCE TO RELATED APPLICATIONS

This application claims priority based on Japanese Patent Application No. 2023-062333 filed on Apr. 6, 2023, and the entire contents of the Japanese patent applications are incorporated herein by reference.

### FIELD

The present disclosure relates to a semiconductor device, and more particularly, to a semiconductor device having a field effect transistor.

### BACKGROUND

A high frequency amplifier circuit is used in a base station of mobile communication. There is known a semiconductor device in which a source-grounded field effect transistor (FET) and a gate-grounded FET are cascode-connected as the high frequency amplifier circuit (for example, Non-Patent Document 1: Proceeding of 2019 15th Conference on Ph. D Research in Microelectronics and Electronics (PRIME), pp. 165 to 168, Ferdinando Costanzo et al. “A Ka-band Doherty Power Amplifier using an innovative Stacked-FET Cell”).

### SUMMARY

A semiconductor device according to the present disclosure includes: a substrate; a first FET (Field Effect Transistor) configured to include a first source electrode provided on the substrate, electrically connected to a first reference potential and extending in a first direction, a first gate electrode provided on the substrate, electrically connected to an input terminal and extending in the first direction, and a first drain electrode provided on the substrate and extending in the first direction; a second FET configured to include a second source electrode provided on the substrate and extending in the first direction, a second gate electrode provided on the substrate and extending in the first direction, and a second drain electrode provided on the substrate, electrically connected to an output terminal and extending in the first direction, the second FET being arranged in the first direction with respect to the first FET; a first wiring configured to electrically connect the first drain electrode to the second source electrode; and a capacitor configured to be provided between the first FET and the second FET, and have a first end electrically connected to the second gate electrode and a second end electrically connected to a second reference potential.

### BRIEF DESCRIPTION OF DRAWINGS

FIG. 1 is a circuit diagram of an amplifier circuit according to a first embodiment.

FIG. 2 is a circuit diagram of an amplifier circuit according to the first embodiment.

FIG. 3 is a plan view of a semiconductor device according to the first embodiment.

FIG. 4 is a cross-sectional view taken along line A-A of FIG. 3.

FIG. 5 is a cross-sectional view taken along line B-B of FIG. 3.

FIG. 6 is a cross-sectional view taken along line C-C of FIG. 3.

FIG. 7 is a cross-sectional view taken along line D-D of FIG. 3.

FIG. 8 is a cross-sectional view taken along line E-E of FIG. 3.

FIG. 9 is a cross-sectional view taken along line F-F of FIG. 3.

FIG. 10 is a cross-sectional view taken along line G-G of FIG. 3.

FIG. 11 is a circuit diagram of an amplifier circuit according to a first comparative example.

FIG. 12 is a plan view of a semiconductor device according to the first comparative example.

FIG. 13 is an enlarged plan view of an FET 52a according to a second embodiment.

FIG. 14 is an enlarged plan view of an FET 52b according to the second embodiment.

FIG. 15 is a cross-sectional view of the FETs 52a and 52b according to the second embodiment.

### DETAILED DESCRIPTION OF EMBODIMENTS

In a high-output amplifier circuit, the FETs are connected in parallel to increase the output. However, if the FETs are connected in parallel in the cascode-connected amplifier circuit, the FETs do not operate uniformly, and the characteristics of the amplifier circuit deteriorate.

The present disclosure has been made in view of the above problem, and an object of the present disclosure is to improve the characteristics of a semiconductor device.

### DETAILS OF EMBODIMENTS OF THE PRESENT DISCLOSURE

First, the contents of the embodiments of this disclosure are listed and explained.
(1) A semiconductor device according to the present disclosure includes: a substrate; a first FET (Field Effect Transistor) configured to include a first source electrode provided on the substrate, electrically connected to a first reference potential and extending in a first direction, a first gate electrode provided on the substrate, electrically connected to an input terminal and extending in the first direction, and a first drain electrode provided on the substrate and extending in the first direction; a second FET configured to include a second source electrode provided on the substrate and extending in the first direction, a second gate electrode provided on the substrate and extending in the first direction, and a second drain electrode provided on the substrate, electrically connected to an output terminal and extending in the first direction, the second FET being arranged in the first direction with respect to the first FET; a first wiring configured to electrically connect the first drain electrode to the second source electrode; and a capacitor configured to be provided between the first FET and the second FET, and have a first end electrically connected to the second gate electrode and a second end electrically connected to a second reference potential. This makes it possible to make the FET characteristics uniform even when the output is increased, thereby improving the characteristics of the semiconductor device.
(2) In the above (1), the first FET may have a plurality of first FETs, the second FET may have a plurality of second FETs, and the capacitor may have a plurality of capacitors. The plurality of first FETs, the plurality of second FETs, and the plurality of capacitors may be arranged in a second direction intersecting the first direction. This enables the scaling of the characteristics of the plurality of first FETs and the plurality of second FETs.
(3) In the above (2), each of the first FETs may include a plurality of first source electrodes arranged in the second direction, a plurality of first drain electrodes arranged alternately with the plurality of first source electrodes in the second direction, and a plurality of first gate electrodes. One of the plurality of first gate electrodes may be arranged between one of the plurality of first source electrodes and one of the plurality of first drain electrodes in the second direction. Each of the second FETs may include a plurality of second source electrodes arranged in the second direction, a plurality of second drain electrodes arranged alternately with the plurality of second source electrodes in the second direction, and a plurality of second gate electrodes. One of the plurality of second gate electrodes may be arranged between one of the plurality of second source electrodes and one of the plurality of second drain electrodes in the second direction. This allows the gate widths of the plurality of first FETs and the plurality of second FETs to be increased.
(4) In the above (3), the semiconductor device further may include a second wiring configured to electrically connect the plurality of second source electrodes in the plurality of second FETs to the first wiring and be provided above the plurality of second FETs. This allows the plurality of second source electrodes to be electrically connected to the first wiring.
(5) In the above (3) or (4), the semiconductor device further may include a first drain bus bar configured to connect the plurality of first drain electrodes in the plurality of first FETs to each other and be provided between the plurality of first FETs and the plurality of capacitors. The first wiring may extend in the first direction between the plurality of capacitors and be connected to the first drain bus bar and a part of the plurality of second source electrodes in each of the plurality of second FETs. This allows the plurality of first drain electrode to be electrically connected to the part of the plurality of second source electrode for each of the plurality of first FETs and each of the plurality of second FETs.
(6) In any one of the above (3) to (5), the semiconductor device further may include a second gate bus bar configured to connect the plurality of second gate electrodes in the plurality of second FETs to each other and be provided between the plurality of second FETs and the plurality of capacitors. This allows each of the capacitors to be provided between the first wirings.
(7) In the above (6), each of the plurality of capacitors may include a lower electrode provided on the substrate, a dielectric layer provided on the lower electrode, and an upper electrode provided on the dielectric layer, and the second gate bus bar may be electrically connected to the upper electrode of each of the plurality of capacitors. This allows the second gate electrodes to be electrically connected to the capacitors.
(8) In the above (7), the semiconductor device further may include a metal layer configured to be provided under the substrate. The lower electrode of each of the plurality of capacitors may be connected to the metal layer via a first via hole penetrating through the substrate. This allows the second reference potential to be supplied to the second gate electrodes via the capacitors.
(9) In the above (7) or (8), the semiconductor device further may include a resistor configured to be provided on the substrate. The resistor may have a first end connected to the second gate bus bar and a second end connected to the upper electrode of a corresponding capacitor. This allows the resistor and the capacitor to be connected between the second gate electrode and the second reference potential.

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

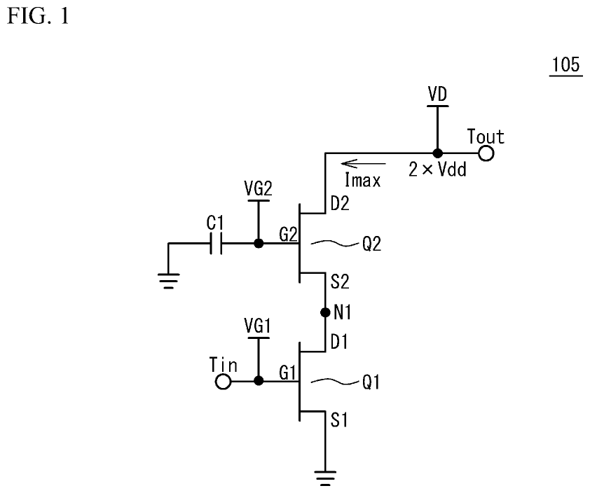

FIG. 1 is a circuit diagram of the amplifier circuit according to a first embodiment. As illustrated in FIG. 1, an amplifier circuit 105 includes FETs Q1 and Q2 that are cascode-connected. The FET Q1 is a source-grounded FET. The FET Q2 is a gate-grounded FET. A source S1 of the FET Q1 is connected to a ground in a high frequency manner. A gate G1 is connected to an input terminal Tin, and a high frequency signal is input to the gate G1. A drain D1 of the FET Q1 and a source S2 of the FET Q2 are electrically connected in common to a node N1. That is, the source S2 of the FET Q2 is electrically connected to the drain D1 of the FET Q1. A gate G2 of the FET Q2 is connected to the ground via a capacitor C1 in a high frequency manner. A drain D2 is connected to an output terminal Tout from which a high frequency signal is output.

A gate bias voltage VG1 of the FET Q1 is applied to the gate G1. A gate bias voltage VG2 of the FET Q2 is applied to the gate G2. A drain bias voltage VD of the FET Q2 is applied to the drain D2 of the FET Q2. An impedance matching circuit (not illustrated) and a bias circuit (not illustrated) that supplies the gate bias voltage VG1 to the gate G1 are connected between the gate G1 and the input terminal Tin. A bias circuit (not illustrated) that supplies the gate bias voltage VG2 to the gate G2 is connected to the gate G2. An impedance matching circuit (not illustrated) and a bias circuit (not illustrated) that supplies the drain bias voltage VD to the drain D2 are connected between the drain D2 and the output terminal Tout. The gate widths of the FETs Q1 and Q2 may be the same as each other or different from each other.

A center frequency of the band of the amplifier circuit 105 is, for example, 0.5 GHz to 10 GHz, and the amplifier circuit 105 is used in, for example, the base station of the mobile communication.

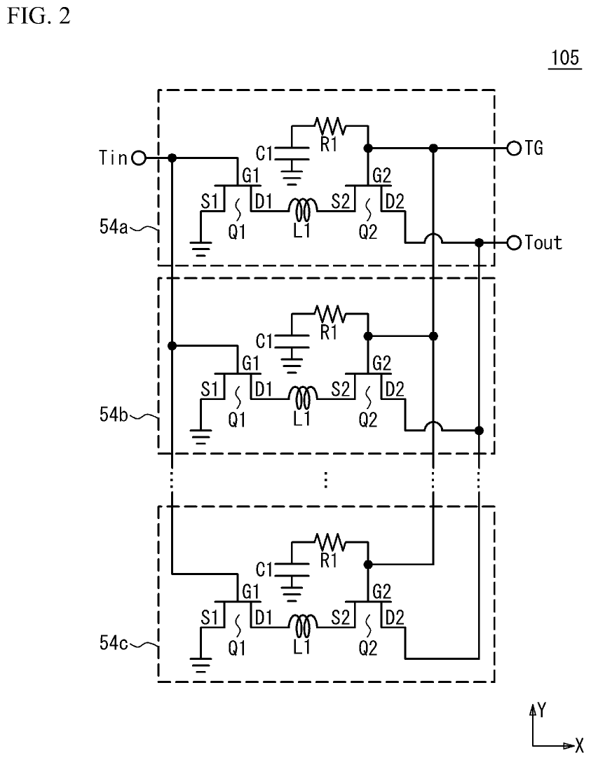

FIG. 2 is a circuit diagram of an amplifier circuit according to the first embodiment. FIG. 2 is illustrated in consideration of the physical positions of the respective elements. An arrangement direction of unit cells 54a to 54c is defined as a Y direction, and an arrangement direction of the FETs Q1 and Q2 is defined as an X direction.

As illustrated in FIG. 2, in the amplifier circuit 105 of the first embodiment, the plurality of unit cells 54a to 54c are arranged in the Y direction. The number of the unit cells 54a to 54c may be 4 or more. The circuit configurations of the unit cells 54a to 54c are the same as each other. The FETs Q1 and Q2 are arranged in the X direction, and capacitors C1 and resistors R1 are provided between the FETs Q1 and the FETs Q2.

The sources S1 of the FETs Q1 are grounded, and the gates G1 are electrically connected to the input terminal Tin in common. The drains D1 of the FETs Q1 and the sources S2 of the FETs Q2 are electrically connected and short-circuited by wirings. Each inductance L1 indicate an inductance of the wiring. The gates G2 of the FETs Q2 are grounded through the resistors R1 and the capacitors C1 in series. Nodes between the gate G2 of the FETs Q2 and the resistors R1 are electrically connected to a gate bias terminal TG (a terminal to which the gate bias voltage VG2 is applied in FIG. 1) in common. The drains D2 are electrically connected to the output terminal Tout in common.

By connecting the unit cells 54a to 54c having the same circuit configuration in parallel, the non-uniformity of the characteristics of the FETs Q1 and the non-uniformity of the characteristics of the FETs Q2 can be suppressed even when the FETs Q1 are connected in parallel and the FETs Q2 are connected in parallel for higher output. Details will be described later.

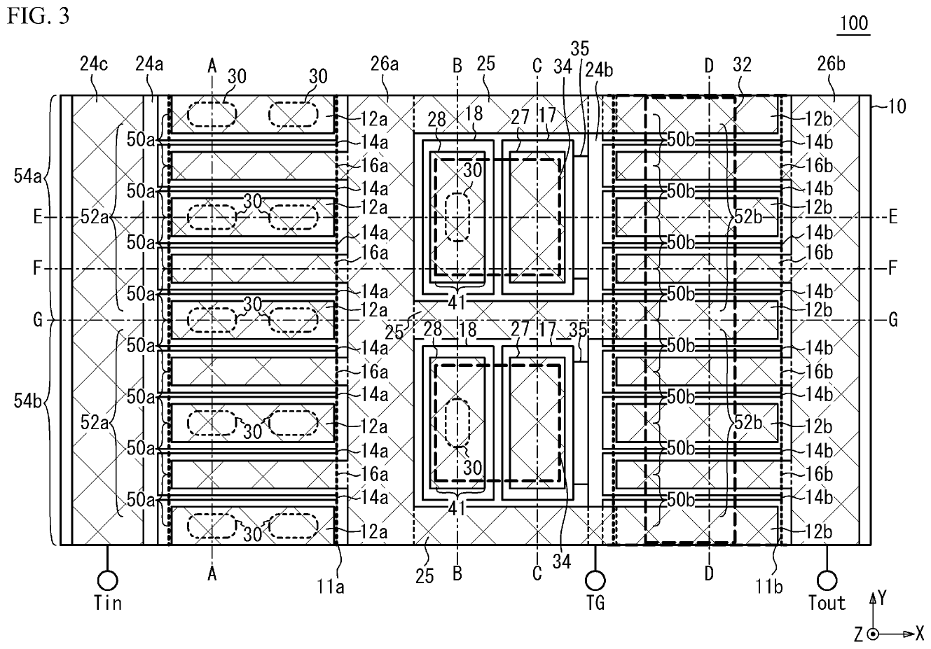

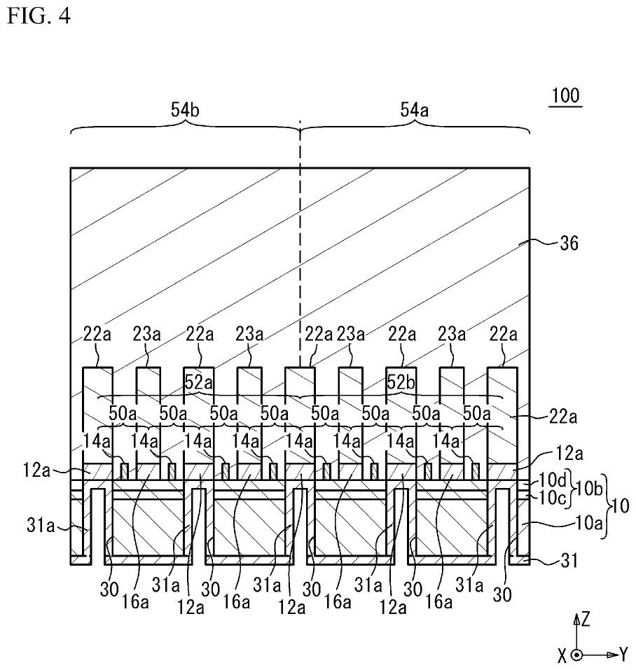

FIG. 3 is a plan view of a semiconductor device according to the first embodiment. FIGS. 4 to 10 are a cross-sectional view taken along the line A-A in FIG. 3, a cross-sectional view taken along the line B-B in FIG. 3, a cross-sectional view taken along the line C-C in FIG. 3, a cross-sectional view taken along the line D-D in FIG. 3, a cross-sectional view taken along the line E-E in FIG. 3, a cross-sectional view taken along the line F-F in FIG. 3, and a cross-sectional view taken along the line G-G in FIG. 3, respectively. In FIGS. 3 to 10, two unit cells 54a and 54b in the plurality of unit cells 54a to 54c are illustrated. An extending direction of the source electrodes 12a and 12b, the gate electrodes 14a and 14b, and the drain electrodes 16a and 16b is defined as the X direction (first direction), and an arrangement direction thereof is defined as the Y direction (second direction intersecting the first direction). A thickness direction of a substrate 10 is defined as the Z direction. A semiconductor device 100 forms at least a part of the amplifier circuit 105.

As illustrated in FIG. 3, in the semiconductor device 100, FETs 52a and 52b are arranged in the X direction in each of the unit cells 54a and 54b. Capacitors 41 and resistors 35 are provided between the FETs 52a (first FET) and the FETs 52b (second FET). Wirings 25 connect the FETs 52a to the FETs 52b, and are provided with the capacitor 41 and the resistor 35 interposed therebetween in the Y direction. The FETs 52a and 52b correspond to the FETs Q1 and Q2 of FIG. 2, respectively. The capacitor 41 and the resistor 35 correspond to the capacitor C1 and the resistor R1 in FIG. 2, respectively.

The FET 52a includes a plurality of source electrodes 12a (first source electrodes), a plurality of gate electrodes 14a (second gate electrodes), and a plurality of drain electrodes 16a (first drain electrodes). The plurality of source electrodes 12a, the plurality of gate electrodes 14a, and the plurality of drain electrodes 16a are provided in an active region 11a on the substrate 10, extend in the X direction, and are arranged in the Y direction. The plurality of source electrodes 12a and the plurality of drain electrodes 16a are provided alternately. One gate electrode 14a is provided between one of the source electrodes 12a and one of the drain electrodes 16a. One gate electrode 14a, and the source electrode 12a and the drain electrode 16a provided with the one gate electrode 14a interposed therebetween form a unit FET 50a.

A gate bus bar 24a (first gate bus bar) connects the plurality of gate electrodes 14a in the plurality of unit cells 54a and 54b to each other, extends in the Y direction, and is provided on an inactive region 13 (see FIGS. 4 to 10) of the substrate 10. A drain bus bar 26a (second drain bus bar) connects the plurality of drain electrodes 16a in the plurality of unit cells 54a and 54b to each other, extends in the Y direction, and is provided on the inactive region 13 of the substrate 10. The gate bus bar 24a and the drain bus bar 26a are provided with the FET 52a interposed therebetween in the X direction. The drain bus bar 26a is provided between the FET 52a and the capacitor 41 in the X direction. A wiring 24c which is electrically connected to the gate bus bar 24a and extends in the Y direction is provided on the gate bus bar 24a. The wiring 24c is electrically connected to the input terminal Tin and is short-circuited. Via holes 30 are provided so as to overlap the plurality of source electrodes 12a of the FETs 52a in the plurality of unit cells 54a and 54b.

The FET 52b includes a plurality of source electrodes 12b (second source electrodes), a plurality of gate electrodes 14b (second gate electrodes), and a plurality of drain electrodes 16b (second drain electrodes). The plurality of source electrodes 12b, the plurality of gate electrodes 14b, and the plurality of drain electrodes 16b are provided in an active region 11b on the substrate 10, extend in the X direction, and are arranged in the Y direction. The plurality of source electrodes 12b and the plurality of drain electrodes 16b are provided alternately. One gate electrode 14b is provided between one of the source electrodes 12b and one of the drain electrodes 16b. One gate electrode 14b, and the source electrode 12b and the drain electrode 16b provided with the one gate electrode 14b interposed therebetween form a unit FET 50b.

A gate bus bar 24b (second gate bus bar) connects the plurality of gate electrodes 14b in the plurality of unit cells 54a and 54b to each other, extends in the Y direction, and is provided on the inactive region 13 of the substrate 10. The gate bus bar 24b is electrically connected to the gate bias terminal TG and is short-circuited. A drain bus bar 26b (second drain bus bar) connects the plurality of drain electrodes 16b in the plurality of unit cells 54a and 54b to each other, extends in the Y direction, and is provided on the inactive region 13 of the substrate 10. The drain bus bar 26b is electrically connected to the output terminal Tout and is short-circuited. The gate bus bar 24b and the drain bus bar 26b are provided with the FET 52b interposed therebetween in the X direction. The gate bus bar 24b is provided between the FET 52b, and the capacitor 41 and the resistor 35 in the X direction. A wiring 32 (second wiring) connects the plurality of source electrodes 12b of the FETs 52 b in the plurality of unit cells 54a and 54b to each other, extends in the Y direction, and is provided above the FETs 52b. The wiring 25 (first wiring) electrically connects the drain bus bar 26a to a part of the source electrodes 12b in the plurality of source electrodes 12b, extends in the X direction, and is provided on the inactive region 13 of the substrate 10. The wiring 25 extending in the X direction and the gate bus bar 24b extending in the Y direction intersect each other without contact.

Metal layers 17 and 18 are provided on the inactive region 13 of the substrate 10. The resistor 35 is provided between the metal layer 17 and the gate bus bar 24b. A + side of the resistor 35 in the X direction is electrically connected to the gate bus bar 24b and is short-circuited. A − side of the resistor 35 in the X direction is electrically connected to the metal layer 17 and is short-circuited. A metal layer 27 is provided on the metal layer 17, and the metal layers 17 and 27 are electrically connected and short-circuited. A wiring 34 (third wiring) is electrically connected to and short-circuited with the metal layer 27 of each of the unit cells 54a and 54b.

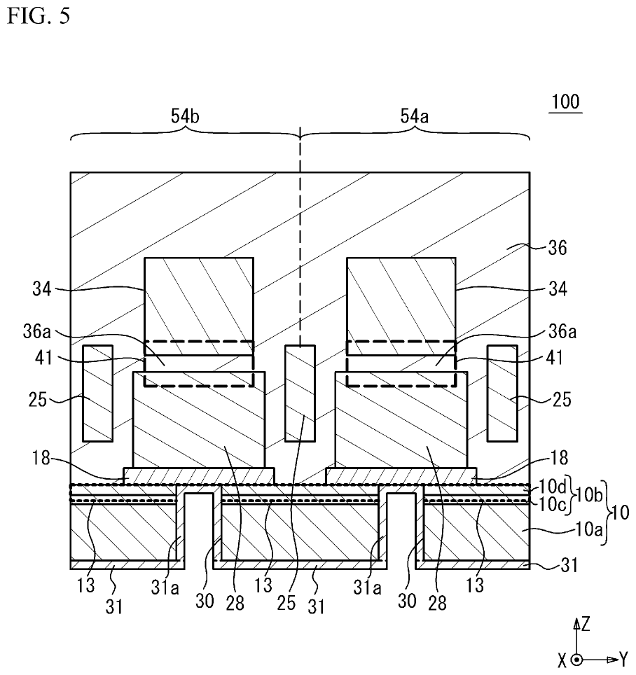

A metal layer 28 is provided on the metal layer 18, and the metal layers 18 and 28 are electrically connected to each other. A dielectric layer 36a (see FIG. 5) is provided between the metal layer 28 and the wiring 34. The metal layer 28, the dielectric layer 36a, and the wiring 34 form the capacitor 41. The via hole 30 is provided so as to overlap the metal layer 18.

As illustrated in FIGS. 4 to 10, the substrate 10 includes a substrate 10a and a semiconductor layer 10b provided on the substrate 10a. The semiconductor layer 10b includes a channel layer 10c and a barrier layer 10d on the channel layer 10c. A region in which the semiconductor layer 10b is inactivated by ion implantation or the like is the inactive region 13. Regions in which the semiconductor layer 10b is activated other than the inactive region 13 are the active regions 11a and 11b (see FIG. 3). A metal layer 31 is provided on a lower surface of the substrate 10. An insulating layer 36 is provided on the substrate 10 so as to cover the FETs 52a and 52b, the resistor 35, the capacitor 41, and the like.

As illustrated in FIG. 4, the source electrode 12a, the gate electrode 14a, and the drain electrode 16a are provided on the semiconductor layer 10b. A source wiring 22a and a drain wiring 23a are provided on the source electrode 12a and the drain electrode 16a, respectively. The source electrode 12a and the source wiring 22a are electrically connected and are short-circuited. The drain electrode 16a and the drain wiring 23a are electrically connected and are short-circuited. The via hole 30 is formed through the substrate 10 so as to overlap the source electrode 12a. A metal layer 31a is provided on an inner surface of the via hole 30. The source electrode 12a is electrically connected to the metal layer 31 via the metal layer 31a and is short-circuited. When a reference potential such as a ground potential is supplied to the metal layer 31, a reference potential (first reference potential) is supplied to the source electrode 12a.

As illustrated in FIG. 5, the wiring 25 is provided on the inactive region 13 of the substrate 10 through the insulating layer 36. The metal layer 18 is provided on the inactive region 13 of the substrate 10. The metal layer 28 is provided on the metal layer 18, and the metal layers 18 and 28 are electrically connected and short-circuited. On the metal layer 28, the wiring 34 is provided with the dielectric layer 36a interposed therebetween. The dielectric layer 36a, and the metal layer 28 and the wiring 34 provided with the dielectric layer 36a interposed therebetween form the capacitor 41. The metal layer 28 forms a lower electrode of the capacitor 41, and the wiring 34 forms an upper electrode of the capacitor 41. The via hole 30 is provided so as to overlap the metal layer 18. The metal layer 18 is electrically connected to the metal layer 31 via the metal layer 31a and is short-circuited. When the reference potential such as the ground potential is supplied to the metal layer 31, the reference potential (second reference potential) is supplied to the metal layers 18 and 28.

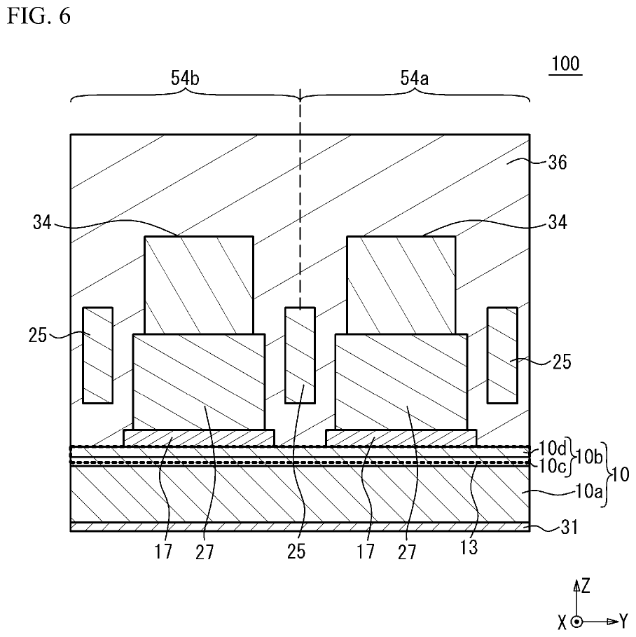

As illustrated in FIG. 6, the wiring 25 is provided on the inactive region 13 of the substrate 10 via the insulating layer 36. The metal layer 17 is provided on the inactive region 13 of the substrate 10. The metal layer 27 is provided on the metal layer 17. The wiring 34 is provided on the metal layer 27. The metal layer 27 and the wiring 34 are electrically connected and short-circuited.

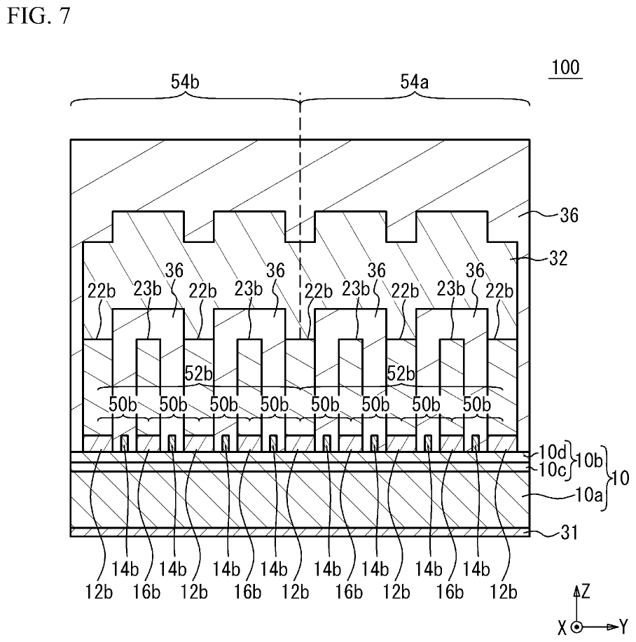

As illustrated in FIG. 7, the source electrode 12b, the gate electrode 14b, and the drain electrode 16b are provided on the active region 11b of the semiconductor layer 10b. A source wiring 22b and a drain wiring 23b are provided on the source electrode 12b and the drain electrode 16b, respectively. The source electrode 12b and the source wiring 22b are electrically connected and are short-circuited. The drain electrode 16b and the drain wiring 23b are electrically connected and are short-circuited. The wiring 32 is provided on the source wiring 22b, and is electrically connected to and short-circuited with the source wiring 22b. The wiring 32 is provided on the drain wiring 23b with the insulating layer 36 interposed therebetween, and is not electrically connected to the drain wiring 23b.

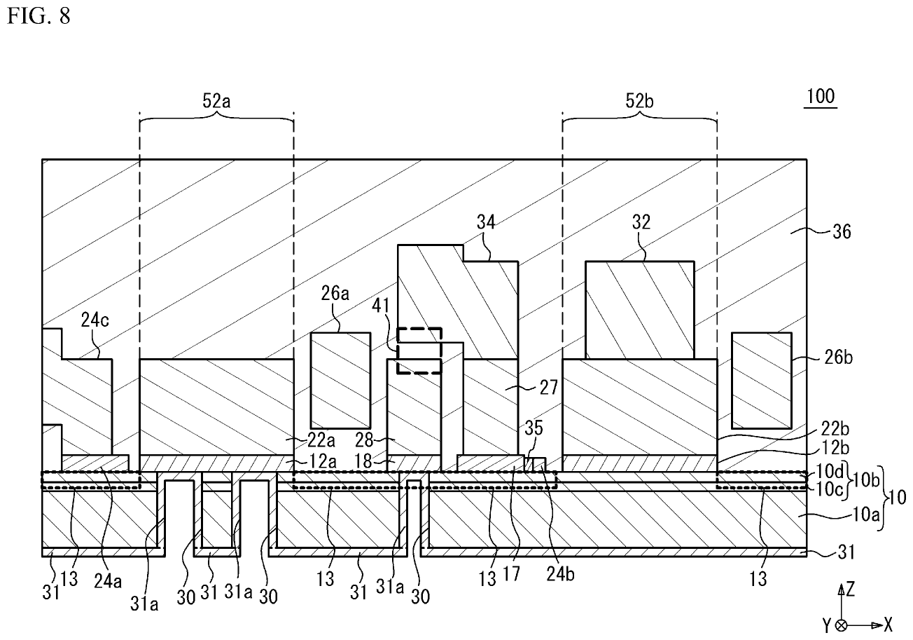

As illustrated in FIG. 8, the gate bus bars 24a and 24b and the resistor 35 are provided on the inactive region 13 of the substrate 10. The drain bus bars 26a and 26b are provided on the inactive region 13 of the substrate 10 via the insulating layer 36. The wiring 24c is provided on the gate bus bar 24a, and the gate bus bar 24a and the wiring 24c are electrically connected and short-circuited.

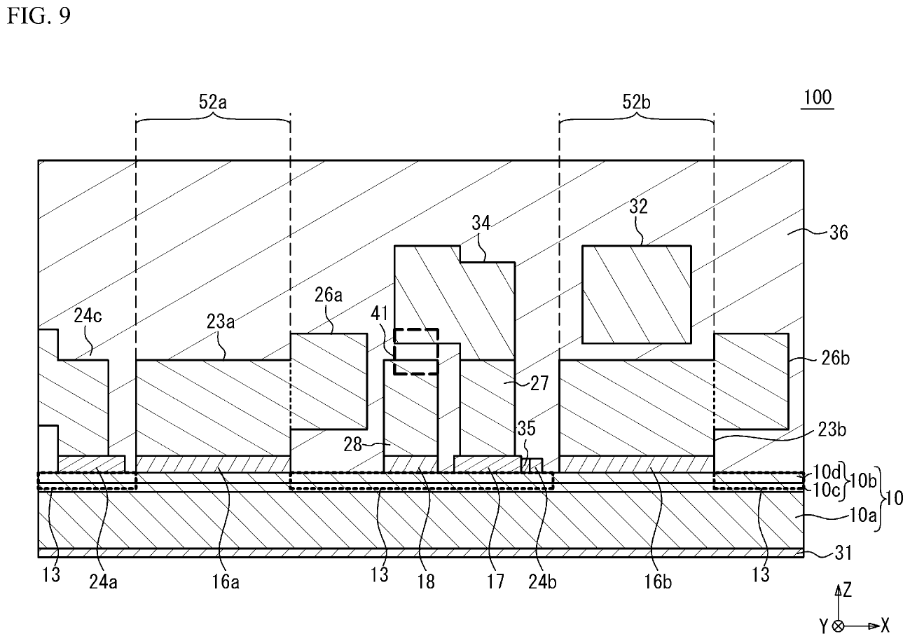

As illustrated in FIG. 9, the drain wiring 23a and the drain bus bar 26a are electrically connected and short-circuited. The drain wiring 23b and the drain bus bar 26b are electrically connected and short-circuited.

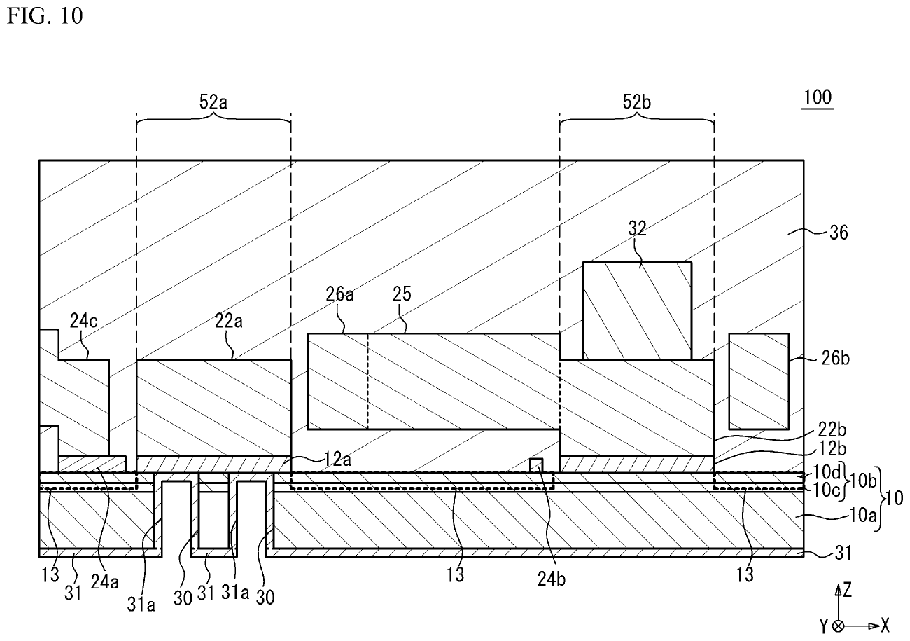

As illustrated in FIG. 10, the wiring 25 is electrically connected to and short-circuited with the drain bus bar 26a and the source wiring 22b. The wiring 25 and the gate bus bar 24b are provided with the insulating layer 36 interposed therebetween, and are electrically insulated from each other by the insulating layer 36.

In FIGS. 4 to 10, the source electrodes 12a and 12b, the drain electrodes 16a and 16b, and the metal layer 18 are formed, for example, simultaneously and are formed of the same metal layer. The gate electrodes 14a and 14b, the metal layer 17, and the gate bus bars 24a and 24b are formed simultaneously, for example, and are formed of the same metal layer. The source wirings 22a and 22b, the drain wirings 23a and 23b, the wiring 24c, the wiring 25, the drain bus bars 26a and 26b, and the metal layers 27 and 28 are formed simultaneously, for example, and are formed of the same metal layer. The wirings 32 and 34 are formed, for example, simultaneously and are formed of the same metal layer.

When the FETs 52a and 52b are GaN HEMTs (Gallium Nitride High Electron Mobility Transistor), the substrate 10 is, for example, a silicon carbide (SiC) substrate, a sapphire substrate, or a gallium nitride (GaN) substrate. The channel layer 10c is a gallium nitride layer, and the barrier layer 10d is an aluminum gallium nitride (AlGaN) layer, for example.

The source electrodes 12a and 12b, the drain electrodes 16a and 16b, and the metal layer 18 are metal layers, for example, each of which includes a titanium layer and an aluminum layer stacked in this order from the semiconductor layer 10b. The gate electrodes 14a and 14b, the metal layer 17, and the gate bus bars 24a and 24b are metal layers, for example, each of which includes a nickel layer and a gold layer stacked in this order from the semiconductor layer 10b. The source wirings 22a and 22b, the drain wirings 23a and 23b, the wirings 24c, the wirings 25, the drain bus bars 26a and 26b, the metal layers 27 and 28, and the wirings 32 and 34 are metal layers, for example, gold layers.

The insulating layer 36 is an inorganic insulating film such as a silicon nitride film. At least a part of the insulating layer 36 may be an organic insulating film such as a polyimide film or a BCB (benzocyclobutene) film. The dielectric layer 36a is an inorganic insulating film such as a silicon nitride film. Each of the FETs 52a and 52b may be an FET other than GaN HEMT, and may be, for example, a LDMOS (Laterally Diffused Metal Oxide Semiconductor).

The gate lengths of the unit FETs 50a and 50b are, for example, 0.5 μm to 5.0 μm. The gate lengths of the unit FETs 50a and 50b are, for example, 10 μm to 100 μm.

### First Comparative Example

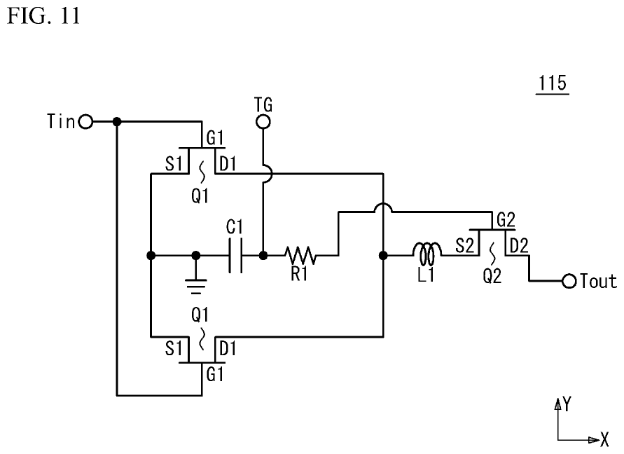

A first comparative example is an example of an amplifier circuit based on a topology 3 in the Non-Patent Document 1. FIG. 11 is a circuit diagram of the amplifier circuit according to the first comparative example. FIG. 11 is illustrated in consideration of the physical positions of the respective elements. As illustrated in FIG. 11, an amplifier circuit 115 of the first comparative example is provided with two FETs Q1 and one FET Q2. The two FETs Q1 are arranged in the Y direction. The capacitor C1 and the resistor R1 are provided between the two FETs Q1. The capacitor C1, the resistor R1, and the FET Q2 are arranged in the X direction. The drains D1 of the FETs Q1 are connected in common and are electrically connected to the source S2 of the FET Q2. The inductance L1 corresponding to the wiring is connected between the drains D1 of the FETs Q1 and the source S2 of the FET Q2. In the first comparative example, no unit cell is provided.

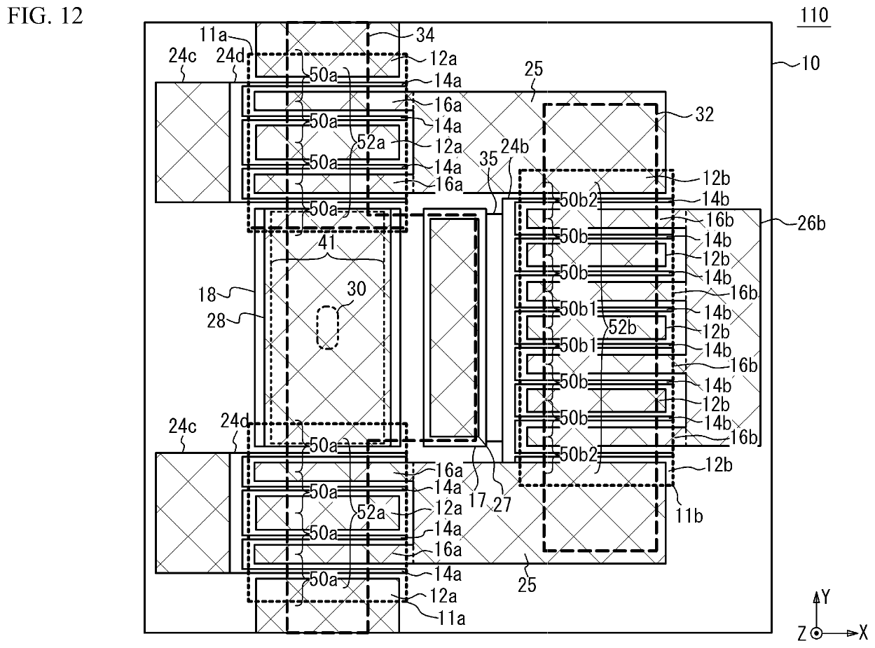

FIG. 12 is a plan view of a semiconductor device according to the first comparative example. A semiconductor device 110 is at least a part of the amplifier circuit 115. As illustrated in FIG. 12, in the semiconductor device 110, two FETs 52a are arranged in the Y direction. The FET 52a includes the plurality of unit FETs 50a arranged in the Y direction. The capacitor 41 is provided between the two FETs 52a in the Y direction. The wiring 34 forming the upper electrode of the capacitor 41 extends in the Y direction, and is electrically connected to the source electrode 12a of the FET 52a, and is not electrically connected to the drain electrode 16a. The metal layers 28 and 18 forming the lower electrode of the capacitor 41 are electrically connected to the metal layer on the lower surface of the substrate 10 via the via hole 30.

Two wirings 25 are connected to the drain electrodes 16a of the two FETs 52a, respectively, and extend in the X direction. The resistor 35 and the FET 52b are provided between the two wirings 25 in the Y direction. The FET 52b includes the plurality of unit FETs 50b. The wiring 32 is provided above the FET 52b and extends in the Y direction. The wiring 32 is electrically connected to the source electrode 12b and is not electrically connected to the drain electrode 16b. The resistor 35 is provided between the gate bus bar 24b and the metal layers 17 and 27 in the X direction. The metal layer 27 is electrically connected to the wiring 34.

The FETs 52a and 52b correspond to the FETs Q1 and Q2 of FIG. 11, respectively. The capacitor 41 and the resistor 35 correspond to the capacitor C1 and the resistor R1 in FIG. 11, respectively.

In the first comparative example, the wirings 25 can be made thick. Therefore, the resistance between the drain electrode 16a and the source electrode 12b can be reduced, and the inductance can be reduced. However, in order to increase the gate width of the FET 52a and the FET 52b for higher output, the number of the unit FETs 50a in the FET 52a is increased, and the number of the unit FETs 50b in the FET 52b is increased. For example, the units FET 50b at the center of the FET 52b in the Y direction are defined as unit FETs 50b1, and the units FET 50b at the ends of the FET 52b in the Y direction are defined as unit FETs 50b2. In the units FET 50b1, the wiring 32 between the source electrode 12b and the wiring 25 is long. This increases the inductance L1 in FIG. 11. In the units FET 50b2, the wiring 32 between the source electrode 12b and the wiring 25 is short. This reduces the inductance L1 in FIG. 11. Therefore, the inductance L1 between the drain electrode 16a and the source electrode 12b of the FET 52a in unit FETs 50b1 is larger than in the unit FETs 50b2. Thus, the characteristics of the unit FETs 50b in the FET 52b become ununiform. Similarly, the characteristics of the unit FETs 50a in the FETs 52a become ununiform.

As described above, in the first comparative example, when the sizes of the FETs 52a and 52b are increased for higher output, the characteristics of the unit FETs 50a become ununiform, and the characteristics of the unit FET 50b become ununiform. Therefore, the characteristics of small-sized FETs 52a and 52b cannot be applied to large-sized FETs 52a and 52b. Thus, the scaling of the characteristics cannot be performed. Therefore, the design of the amplifier circuit 115 is not easy.

### Description of First Embodiment

In contrast, according to the semiconductor device 100 of the first embodiment, as illustrated in FIG. 3, the arrangement direction of the FETs 52a (first FET) and 52b (second FET) is the same X direction (first direction) as the extending direction of the source electrodes 12a (first source electrodes) and 12b (second source electrodes), the gate electrodes 14a (first gate electrodes) and 14b (second gate electrodes), and the drain electrodes 16a (first drain electrodes) and 16b (second drain electrodes). The capacitor 41 is provided between the FETs 52a and 52b, and has a first end electrically connected to the gate electrode 14b of the FET 52b and a second end electrically connected to the second reference potential. The wiring 25 (first wiring) electrically connects the drain electrode 16a of the FET 52a to the source electrode 12b of the FET 52b. Thereby, as illustrated in FIG. 2, the unit cells 54a to 54c can be arranged in the Y direction (second direction). The characteristics of the FETs 52a in the unit cells 54a to 54c are the same as each other, and the characteristics of the FETs 52b in the unit cells 54a to 54c are the same as each other. Therefore, even when the output is increased, the characteristics of the unit FETs 50a in the FETs 52a can be made uniform, and the characteristics of the unit FETs 50b in the FETs 52b can be made uniform. Therefore, the characteristics of the amplifier circuit 105 can be improved.

As illustrated in FIG. 3, the plurality of FETs 52a and 52b and capacitors 41 are arranged in the Y direction. Thereby, as illustrated in FIG. 2, the unit cells 54a to 54c can be arranged in the Y direction (second direction). The characteristics of the unit cells 54a and 54b can be scaled independently of the output power of the amplifier circuit 105. Thus, the design of the amplifier circuit 105 becomes easier.

The FET 52a includes the plurality of source electrodes 12a, the plurality of drain electrodes 16a, and the plurality of gate electrodes 14a. The FET 52b includes the plurality of source electrodes 12b, the plurality of drain electrodes 16b, and the plurality of gate electrodes 14b. This makes it possible to increase the gate width of one FET 52a and the gate width of one FET 52b. When the number of the unit FETs 50b in the FETs 52 b in one unit cell 54a increases, the difference in inductance between the source electrodes 12b of the unit FETs 50b and the wiring 25 increases as in the first comparative example. Therefore, the number of the source electrodes 12b in one unit cell 54a is preferably 5 or less, and is more preferably 3.

The wiring 32 (second wiring) electrically connects the plurality of source electrodes 12b in the plurality of FETs 52b to the wiring 25 to each other, and is provided above the plurality of FETs 52b. This allows the source electrodes 12b to be electrically connected to the wiring 25 even when the number of the source electrodes 12b in one unit cell 54a is 3 or more.

The drain bus bar 26a (first drain bus bar) connects the drain electrodes 16a of the FETs 52a to each other and is provided between the FETs 52a and the capacitor 41. The drain bus bar 26a allow the potentials of the drain electrodes 16a in the unit cells 54a to 54c to be substantially the same. Therefore, the ununiformity in characteristics between the unit cells 54a to 54c can be suppressed. The wiring 25 is connected to the drain bus bar 26a and a part of the source electrodes 12b in the plurality of source electrodes 12b of each of the FETs 52b between the plurality of capacitors 41. Since the wiring 25 is provided between the capacitors 41, the drain electrode 16a can be electrically connected to the source electrode 12b for each of the unit cells 54a to 54c. Therefore, the ununiformity in characteristics between the unit cells 54a to 54c can be suppressed.

The gate bus bar 24b (second gate bus bar) connects the plurality of gate electrodes 14b in the plurality of FETs 52b to each other and is provided between the FETs 52b and the capacitors 41. This allows the gate electrodes 14b in the unit cells 54a to 54c to be electrically connected to the gate bias terminals TG via the gate bus bars 24b.

Each of the capacitors 41 includes the metal layers 18 and 28 (lower electrodes) provided on the substrate 10, the dielectric layer 36a provided on the metal layer 28, and the wiring 34 (upper electrode) provided on the dielectric layer 36a. The gate bus bar 24b is electrically connected to the upper electrode of the corresponding capacitor 41. This allows the gate electrodes 14b of the FET 52b to be electrically connected to the capacitor 41.

The lower electrodes of the capacitors 41 are connected to the metal layer 31 through the via holes 30 (first via holes) penetrating the substrate 10. This allows the gate electrodes 14b to be connected to the second reference potential via the capacitors 41.

The resistor 35 is provided on the substrate 10, and has a first end connected to the gate bus bar 24b and a second end connected to the upper electrode of the capacitor 41. This enables the resistor 35 and the capacitor 41 to be directly connected between the gate electrodes 14b and the second reference potential.

Each of the plurality of source electrodes 12a of the FET 52a is connected to the metal layer 31 via the via holes 30 (second via holes) penetrating the substrate 10. This allows the source electrode 12a to be grounded.

The gate bus bar 24a (first gate bus bar) connects the plurality of gate electrodes 14a in the plurality of FETs 52a to each other, and the plurality of FETs 52a are provided between the gate bus bar 24a and the plurality of capacitors 41. This allows the plurality of gate electrodes 14a to be electrically connected in common.

The drain bus bar 26b (second drain bus bar) connects the plurality of drain electrodes 16b in the plurality of FETs 52b to each other and the plurality of FETs 52b are provided between the drain bus bar 26b and the plurality of capacitors 41. This allows the plurality of drain electrodes 16b to be electrically connected in common.

### Second Embodiment

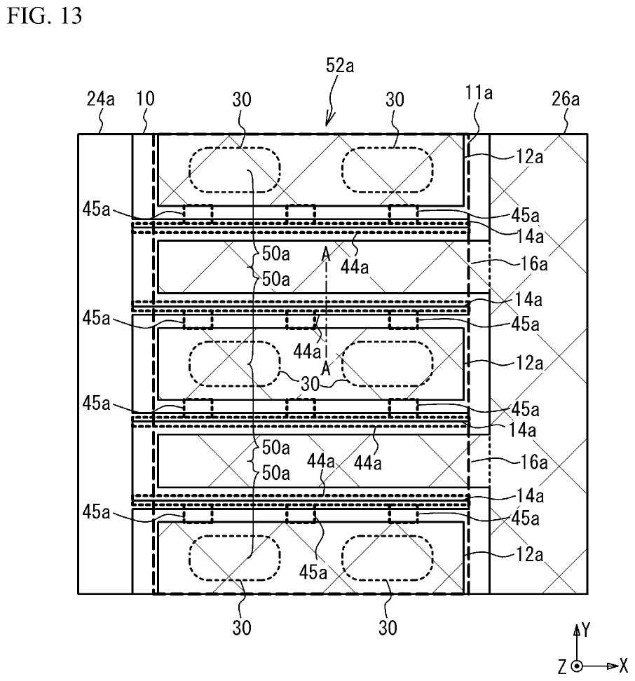

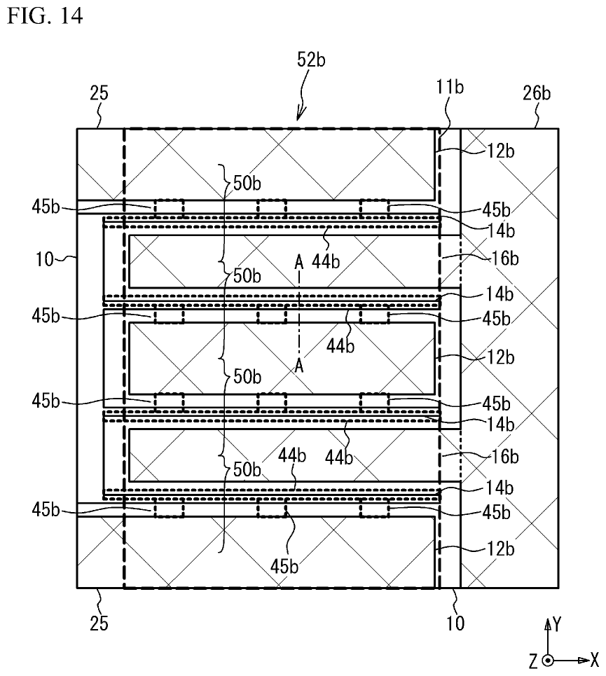

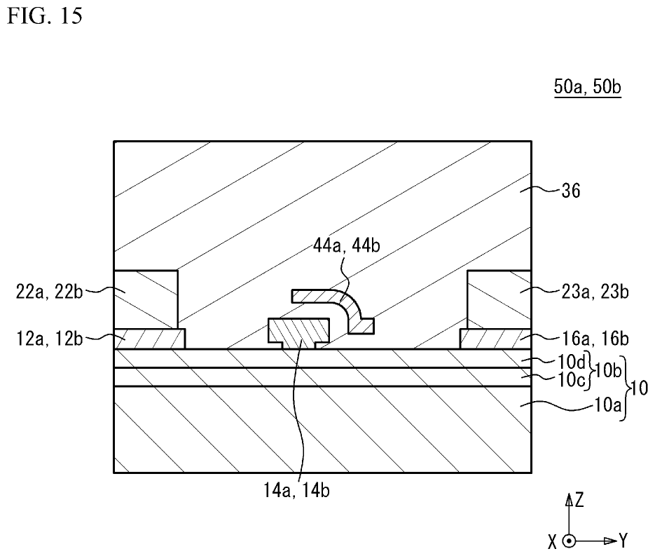

FIG. 13 is an enlarged plan view of the FET 52a according to a second embodiment. FIG. 14 is an enlarged plan view of the FET 52b according to the second embodiment. FIG. 15 is a cross-sectional view of the FETs 52a and 52b according to the second embodiment, and is a cross-sectional view taken along the line A-A in FIGS. 13 and 14.

As illustrated in FIGS. 13 and 15, in the FET 52a, a field plate 44a is provided across the insulating layer 36 and above the semiconductor layer 10b between the gate electrode 14a and the drain electrode 16a. The wiring 45a intersects with the source electrode 12a above the source electrode 12a in a non-contact manner, electrically connects the field plate 44a to the source electrode 12a, and short-circuits the field plate 44a with the source electrode 12a. As a result, the field plate 44a has the same potential (first reference potential) as the source electrode 12a.

As illustrated in FIGS. 14 and 15, in the FET 52b, a field plate 44b is provided across the insulating layer 36 and above the semiconductor layer 10b between the gate electrode 14b and the drain electrode 16b. The wiring 45b intersects with the source electrode 12b above the source electrode 12b in a non-contact manner, electrically connects the field plate 44b to the source electrode 12b, and short-circuits the field plate 44b with the source electrode 12b. As a result, the field plate 44b has the same potential as that of the source electrode 12b.

In the second embodiment, the FET 52a includes the field plate 44a (first field plate) having at least a part thereof provided above the substrate 10 between the gate electrode 14a and the drain electrode 16a. The FET 52b includes the field plate 44b (second field plate) having at least a part thereof provided above the substrate 10 between the gate electrode 14b and the drain electrode 16b. This can suppress the concentration of the electric field in the semiconductor layer 10b between the gate electrode 14a and the drain electrode 16a and between the gate electrode 14b and the drain electrode 16b.

The field plates 44a and 44b are provided so as to extend above the gate electrodes 14a and 14b, respectively. This can suppress the gate-drain capacitances between the gate electrode 14a and the corresponding drain electrode 16a and between the gate electrode 14b and the corresponding drain electrode 16b.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a substrate;
a first FET (Field Effect Transistor) configured to include a first source electrode provided on the substrate, electrically connected to a first reference potential and extending in a first direction, a first gate electrode provided on the substrate, electrically connected to an input terminal and extending in the first direction, and a first drain electrode provided on the substrate and extending in the first direction;
a second FET configured to include a second source electrode provided on the substrate and extending in the first direction, a second gate electrode provided on the substrate and extending in the first direction, and a second drain electrode provided on the substrate, electrically connected to an output terminal and extending in the first direction, the second FET being arranged in the first direction with respect to the first FET;
a first wiring configured to electrically connect the first drain electrode to the second source electrode; and
a capacitor configured to be provided between the first FET and the second FET, and have a first end electrically connected to the second gate electrode and a second end electrically connected to a second reference potential.

2. The semiconductor device according to claim 1, wherein
the first FET has a plurality of first FETs, the second FET has a plurality of second FETs, and the capacitor has a plurality of capacitors,
the plurality of first FETs, the plurality of second FETs, and the plurality of capacitors are arranged in a second direction intersecting the first direction.

3. The semiconductor device according to claim 2, wherein
each of the first FETs includes a plurality of first source electrodes arranged in the second direction, a plurality of first drain electrodes arranged alternately with the plurality of first source electrodes in the second direction, and a plurality of first gate electrodes,
one of the plurality of first gate electrodes is arranged between one of the plurality of first source electrodes and one of the plurality of first drain electrodes in the second direction,
each of the second FETs includes a plurality of second source electrodes arranged in the second direction, a plurality of second drain electrodes arranged alternately with the plurality of second source electrodes in the second direction, and a plurality of second gate electrodes, and
one of the plurality of second gate electrodes is arranged between one of the plurality of second source electrodes and one of the plurality of second drain electrodes in the second direction.

4. The semiconductor device according to claim 3, further comprising:
a second wiring configured to electrically connect the plurality of second source electrodes in the plurality of second FETs to the first wiring and be provided above the plurality of second FETs.

5. The semiconductor device according to claim 3, further comprising:
a first drain bus bar configured to connect the plurality of first drain electrodes in the plurality of first FETs to each other and be provided between the plurality of first FETs and the plurality of capacitors;
wherein the first wiring extends in the first direction between the plurality of capacitors and is connected to the first drain bus bar and a part of the plurality of second source electrodes in each of the plurality of second FETs.

6. The semiconductor device according to claim 3, further comprising:
a second gate bus bar configured to connect the plurality of second gate electrodes in the plurality of second FETs to each other and be provided between the plurality of second FETs and the plurality of capacitors.

7. The semiconductor device according to claim 6, wherein
each of the plurality of capacitors includes a lower electrode provided on the substrate, a dielectric layer provided on the lower electrode, and an upper electrode provided on the dielectric layer, and
the second gate bus bar is electrically connected to the upper electrode of each of the plurality of capacitors.

8. The semiconductor device according to claim 7, further comprising:
a metal layer configured to be provided under the substrate;
wherein the lower electrode of each of the plurality of capacitors is connected to the metal layer via a first via hole penetrating through the substrate.

9. The semiconductor device according to claim 7, further comprising:
a resistor configured to be provided on the substrate, the resistor having a first end connected to the second gate bus bar and a second end connected to the upper electrode of a corresponding capacitor.
